(19) United States
(12) Patent Application Publication
(10) Pub. No.: US 2017/0051407 A1
(43) Pub. Date: Feb. 23, 2017

(54) Heating Source For Spatial Atomic Layer Deposition

(71) Applicant: Applied Materials, Inc., Santa Clara, CA (US)

(72) Inventors: Garry K. Kwong, San Jose, CA (US); Joseph Yudovsky, Campbell, CA (US); Kevin Griffin, Livermore, CA (US); Kallol Bera, Fremont, CA (US); Omer Ozgun, San Jose, CA (US)

(21) Appl. No.: 15/222,010

(22) Filed: Jul. 28, 2016

Related U.S. Application Data
(60) Provisional application No. 62/206,247, filed on Aug. 17, 2015.

(51) Int. Cl. C23C 16/455; C23C 16/458; C23C 16/52; C23C 16/46

(52) U.S. Cl. CPC C23C 16/45544; C23C 16/46; C23C 16/458; C23C 16/52

(57) ABSTRACT

Heating apparatus for heating substrates having a graphite body and at least one heating element comprising a continuous section of material disposed within the body are disclosed. Processing chambers incorporating the heating apparatus are also disclosed.

This application claims priority to U.S. Provisional Application No. 62/206,247, filed Aug. 17, 2015, the entire disclosure of which is hereby incorporated by reference herein.

### FIELD

Embodiments of the disclosure relate to resistive heaters for semiconductor processing. In particular, embodiments of the disclosure are directed to graphite heaters for use in atomic layer deposition batch processing chambers.

### BACKGROUND

Semiconductor device formation is commonly conducted in substrate processing systems or platforms containing multiple chambers, which may also be referred to as cluster tools. In some instances, the purpose of a multi-chamber processing platform or cluster tool is to perform two or more processes on a substrate sequentially in a controlled environment. In other instances, however, a multiple chamber processing platform may only perform a single processing step on substrates. The additional chambers can be employed to maximize the rate at which substrates are processed. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for atomic layer deposition (ALD) processes and some chemical vapor deposition (CVD) processes.

Temperature uniformity may be an important consideration in CVD or ALD process. Resistive heaters are widely employed in the heating systems of CVD and ALD systems. Even slight variations in temperature uniformity across a wafer, on the order of just a few degrees Celsius, can adversely affect a CVD or ALD process. The size of the batch processing chambers further increases the complexity and requirements of the heating sources. Accordingly, there is a need in the art for improved heaters for batch processing chambers

### SUMMARY

One or more embodiments of the disclosure are directed to apparatus comprising a body having a top surface, bottom surface and outer edge. The body comprises graphite and has at least one heating element comprising a continuous section of material disposed therein.

Additional embodiments of the disclosure are directed to processing chambers comprising a gas distribution assembly having a front surface, a susceptor assembly and a heating apparatus. The susceptor assembly has a top surface facing the front surface of the gas distribution assembly and a bottom surface. The top surface has a plurality of recesses therein with each recess sized to support a substrate during processing. The heating apparatus has a body comprising graphite with a top surface facing the bottom surface of the susceptor assembly. The heating apparatus includes at least one heating element within the body.

Further embodiments of the disclosure are directed to processing chambers comprising a gas distribution assembly, a susceptor assembly and a heating apparatus. The gas distribution assembly has a front surface. The susceptor assembly has a top surface facing the front surface of the gas distribution assembly and a bottom surface. The top surface has a plurality of recesses therein with each recess sized to support a substrate during processing. The susceptor assembly is connected to a support post. The heating apparatus has a body comprising substantially only graphite with a top surface facing the bottom surface of the susceptor assembly. The heating apparatus includes at least one heating element within the body connected to a 100V to 500V power source. The heating element is effective to heat the susceptor assembly to a temperature sufficient to heat a substrate positioned on the susceptor assembly to a temperature greater than about 1100° C. The heating apparatus includes an opening passing through the body from the top surface to the bottom surface and the support post passes through the opening in the body without contacting the body

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional view of a batch processing chamber in accordance with one or more embodiment of the disclosure;

FIG. 2 shows a partial perspective view of a batch processing chamber in accordance with one or more embodiment of the disclosure;

FIG. 3 shows a schematic view of a batch processing chamber in accordance with one or more embodiment of the disclosure;

FIG. 4 shows a schematic view of a portion of a wedge shaped gas distribution assembly for use in a batch processing chamber in accordance with one or more embodiment of the disclosure;

FIG. 5 shows a schematic view of a batch processing chamber in accordance with one or more embodiment of the disclosure;

FIG. 6 shows a perspective view of a heating apparatus in accordance with one or more embodiments of the disclosure;

FIG. 7 shows a partial cross-sectional schematic of a heating apparatus in accordance with one or more embodiments of the disclosure; and

FIG. 8 shows a partial schematic of a processing chamber in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways. It is also to be understood that the complexes and ligands of the present disclosure may be illustrated herein using structural formulas which have a particular stereochemistry. These illustrations are intended as examples only and are not to be construed as limiting the disclosed structure to any particular stereochemistry. Rather, the illustrated structures are intended to encompass all such complexes and ligands having the indicated chemical formula.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap. As used in this specification and the appended claims, the terms “precursor”, “reactant”, “reactive gas” and the like are used interchangeably to refer to any gaseous species that can react with the substrate surface.

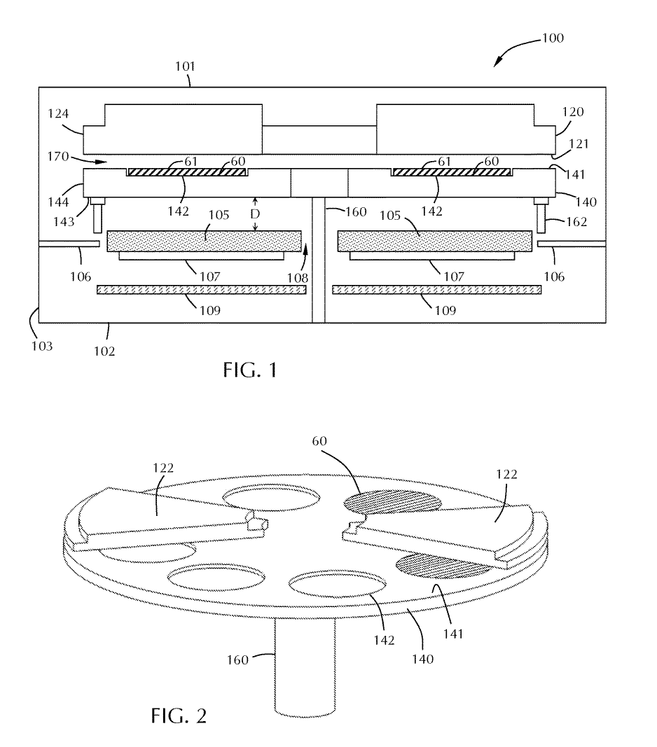

FIG. 1 shows a cross-section of a processing chamber 100 having a top 101, bottom 102 and sides 103. The processing chamber 100 includes a gas distribution assembly 120, also referred to as injectors or an injector assembly, and a susceptor assembly 140. The gas distribution assembly 120 is any type of gas delivery device used in a processing chamber. The gas distribution assembly 120 includes a front surface 121 which faces the susceptor assembly 140. The front surface 121 can have any number or variety of openings to deliver a flow of gases toward the susceptor assembly 140. The gas distribution assembly 120 also includes an outer peripheral edge 124 which in the embodiments shown, is substantially round.

The specific type of gas distribution assembly 120 used can vary depending on the particular process being used. Embodiments of the disclosure can be used with any type of processing system where the gap between the susceptor and the gas distribution assembly is controlled. While various types of gas distribution assemblies can be employed (e.g., showerheads), embodiments of the disclosure may be particularly useful with spatial ALD gas distribution assemblies which have a plurality of substantially parallel gas channels. As used in this specification and the appended claims, the term “substantially parallel” means that the elongate axis of the gas channels extend in the same general direction. There can be slight imperfections in the parallelism of the gas channels. The plurality of substantially parallel gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the processing region through the purge gas P channel(s). A substrate moving from one end of the gas distribution assembly to the other end will be exposed to each of the process gases in turn, forming a layer on the substrate surface.

In some embodiments, the gas distribution assembly 120 is a rigid stationary body made of a single injector unit. In one or more embodiments, the gas distribution assembly 120 is made up of a plurality of individual sectors (e.g., injector units 122), as shown in FIG. 2. Either a single piece body or a multi-sector body can be used with the various embodiments of the disclosure described.

The susceptor assembly 140 is positioned beneath the gas distribution assembly 120. The susceptor assembly 140 includes a top surface 141 and at least one recess 142 in the top surface 141. The susceptor assembly 140 also has a bottom surface 143 and an edge 144. The recess 142 can be any suitable shape and size depending on the shape and size of the substrates 60 being processed. In the embodiment shown in FIG. 1, the recess 142 has a flat bottom to support the bottom of the wafer; however, the bottom of the recess can vary. In some embodiments, the recess has step regions around the outer peripheral edge of the recess which are sized to support the outer peripheral edge of the wafer. The amount of the outer peripheral edge of the wafer that is supported by the steps can vary depending on, for example, the thickness of the wafer and the presence of features already present on the back side of the wafer.

In some embodiments, as shown in FIG. 1, the recess 142 in the top surface 141 of the susceptor assembly 140 is sized so that a substrate 60 supported in the recess 142 has a top surface 61 substantially coplanar with the top surface 141 of the susceptor 140. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

The susceptor assembly 140 of FIG. 1 includes a support post 160 which is capable of lifting, lowering and rotating the susceptor assembly 140. The susceptor assembly may include a heater 105, or gas lines (not shown), or electrical components (not shown) within the center of the support post 160. The support post 160 may be the primary means of increasing or decreasing the gap between the susceptor assembly 140 and the gas distribution assembly 120, moving the susceptor assembly 140 into proper position. The susceptor assembly 140 may also include fine tuning actuators 162 which can make micro-adjustments to susceptor assembly 140 to create a predetermined gap 170 between the susceptor assembly 140 and the gas distribution assembly 120. In some embodiments, the gap 170 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The heater 105 can be a component of the susceptor assembly 140 or a separate component. The heater 105 shown in FIG. 1 is positioned a distance D below the bottom surface 143 of the susceptor assembly 140. Energy from the heater 105 affects the susceptor assembly 140 elevating the temperature of the susceptor assembly 140 and the substrate 60 supported on the susceptor assembly 140. The heater 105 can be a resistive heater or a plurality of lamps.

The heater 105 can be connected to and supported by the susceptor assembly 140 or the support post 160 or a separate heater support 107. The heater support 107 can be smaller than or larger than the heater 105. FIG. 1 shows the heater 105 and heater support 107 as a cross-sectional view and those skilled in the art will understand that any or all of the components of the processing chamber 100 are three-dimensional. For example, the heater 105 of FIG. 1 can be cylindrical in shape with a center opening 108 to allow the support post 160 to pass through. This arrangement allows the support post 160 to move the susceptor assembly 140 independently of the heater 105.

In some embodiments, a reflector 109 is positioned between the heater 105 and the bottom and/or sides (not shown) of the processing chamber 100. The reflector 109 can help prevent damage to the processing chamber by decreasing the amount of radiant energy impacting the processing chamber from the heater 105. The heater support 107 of some embodiments is also a reflector.

The processing chamber 100 shown in the Figures is a carousel-type chamber in which the susceptor assembly 140 can hold a plurality of substrates 60. As shown in FIG. 2, the gas distribution assembly 120 may include a plurality of separate injector units 122, each injector unit 122 being capable of depositing a film on the wafer, as the wafer is moved beneath the injector unit. Two pie-shaped injector units 122 are shown positioned on approximately opposite sides of and above the susceptor assembly 140. This number of injector units 122 is shown for illustrative purposes only. It will be understood that more or less injector units 122 can be included. In some embodiments, there are a sufficient number of pie-shaped injector units 122 to form a shape conforming to the shape of the susceptor assembly 140. In some embodiments, each of the individual pie-shaped injector units 122 may be independently moved, removed and/or replaced without affecting any of the other injector units 122. For example, one segment may be raised to permit a robot to access the region between the susceptor assembly 140 and gas distribution assembly 120 to load/unload substrates 60.

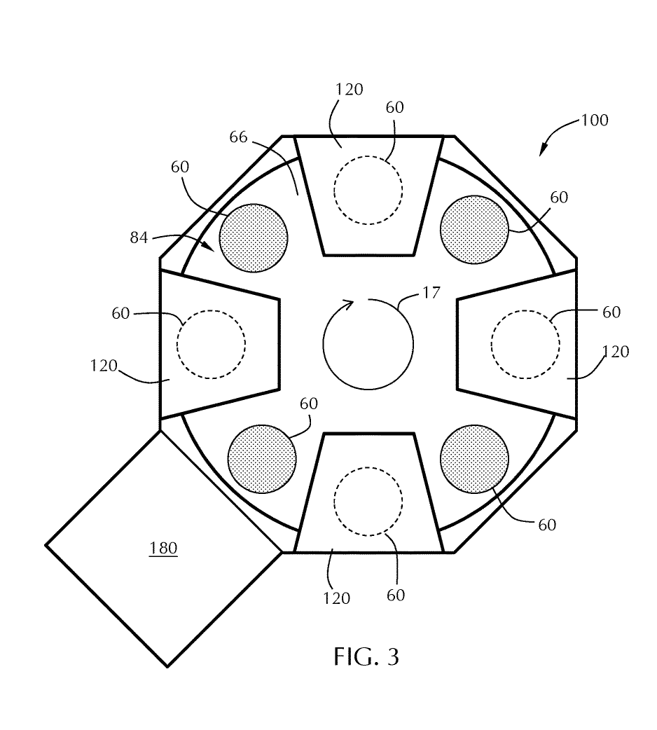

Processing chambers having multiple gas injectors can be used to process multiple wafers simultaneously so that the wafers experience the same process flow. For example, as shown in FIG. 3, the processing chamber 100 has four gas injector assemblies and four substrates 60. At the outset of processing, the substrates 60 can be positioned between the gas distribution assemblies 120. Rotating 17 the susceptor assembly 140 by 45° will result in each substrate 60 which is between gas distribution assemblies 120 to be moved to an gas distribution assembly 120 for film deposition, as illustrated by the dotted circle under the gas distribution assemblies 120. An additional 45° rotation would move the substrates 60 away from the gas distribution assemblies 120. With spatial ALD injectors, a film is deposited on the wafer during movement of the wafer relative to the injector assembly. In some embodiments, the susceptor assembly 140 is rotated in increments that prevent the substrates 60 from stopping beneath the gas distribution assemblies 120. The number of substrates 60 and gas distribution assemblies 120 can be the same or different. In some embodiments, there is the same number of wafers being processed as there are gas distribution assemblies. In one or more embodiments, the number of wafers being processed are fraction of or an integer multiple of the number of gas distribution assemblies. For example, if there are four gas distribution assemblies, there are 4× wafers being processed, where x is an integer value greater than or equal to one.

The processing chamber 100 shown in FIG. 3 is merely representative of one possible configuration and should not be taken as limiting the scope of the disclosure. Here, the processing chamber 100 includes a plurality of gas distribution assemblies 120. In the embodiment shown, there are four gas distribution assemblies (also called gas distribution assemblies 120) evenly spaced about the processing chamber 100. The processing chamber 100 shown is octagonal; however, those skilled in the art will understand that this is one possible shape and should not be taken as limiting the scope of the disclosure. The gas distribution assemblies 120 shown are trapezoidal, but can be a single circular component or made up of a plurality of pie-shaped segments, like that shown in FIG. 2.

The embodiment shown in FIG. 3 includes a load lock chamber 180, or an auxiliary chamber like a buffer station. This chamber 180 is connected to a side of the processing chamber 100 to allow, for example the substrates (also referred to as substrates 60) to be loaded/unloaded from the processing chamber 100. A wafer robot may be positioned in the chamber 180 to move the substrate onto the susceptor.

Rotation of the carousel (e.g., the susceptor assembly 140) can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing steps between each layer deposition (e.g., exposure to plasma).

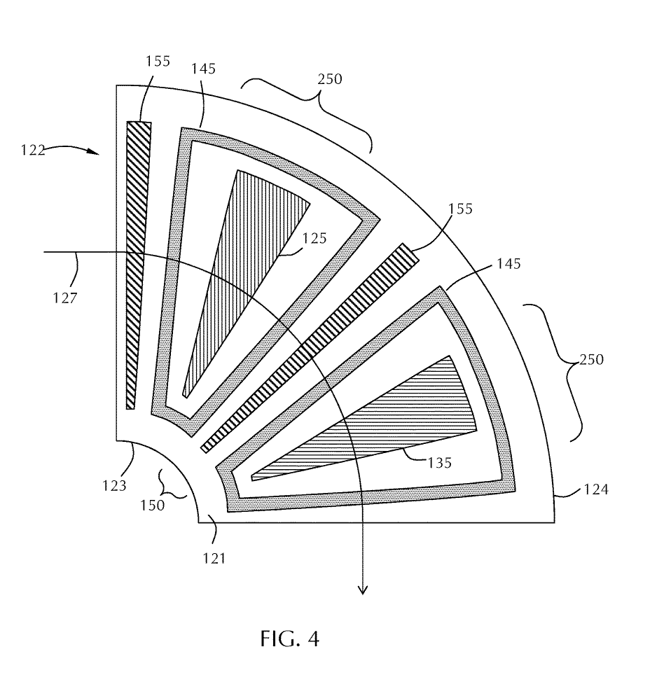

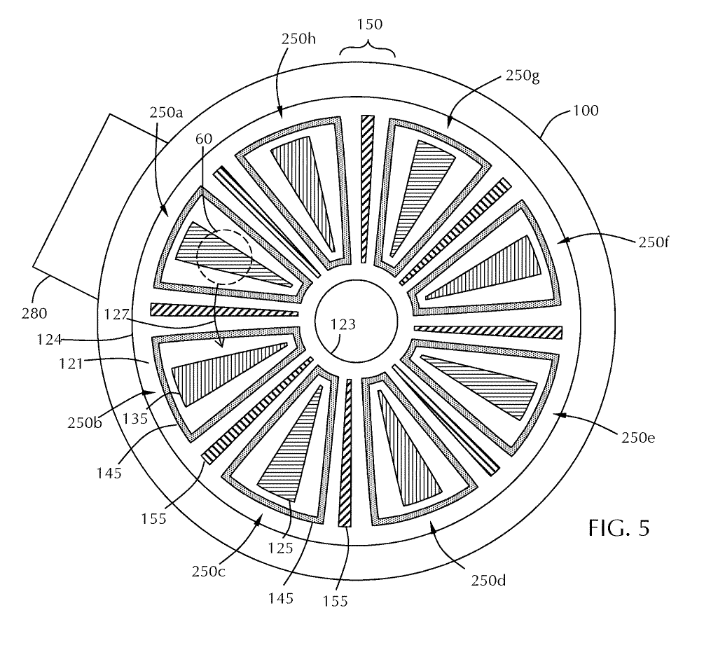

FIG. 4 shows a sector or portion of a gas distribution assembly 120, which may be referred to as an injector unit 122. The injector units 122 can be used individually or in combination with other injector units. For example, as shown in FIG. 5, four of the injector units 122 of FIG. 4 are combined to form a single gas distribution assembly 120. (The lines separating the four injector units are not shown for clarity.) While the injector unit 122 of FIG. 4 has both a first reactive gas port 125 and a second reactive gas port 135 in addition to purge gas ports 155 and vacuum ports 145, an injector unit 122 does not need all of these components.

Referring to both FIGS. 4 and 5, a gas distribution assembly 120 in accordance with one or more embodiment may comprise a plurality of sectors (or injector units 122) with each sector being identical or different. The gas distribution assembly 120 is positioned within the processing chamber and comprises a plurality of elongate gas ports 125, 135, 145 in a front surface 121 of the gas distribution assembly 120. The plurality of elongate gas ports 125, 135, 145, 155 extend from an area adjacent the inner peripheral edge 123 toward an area adjacent the outer peripheral edge 124 of the gas distribution assembly 120. The plurality of gas ports shown include a first reactive gas port 125, a second reactive gas port 135, a vacuum port 145 which surrounds each of the first reactive gas ports and the second reactive gas ports and a purge gas port 155.

With reference to the embodiments shown in FIG. 4 or 5, when stating that the ports extend from at least about an inner peripheral region to at least about an outer peripheral region, however, the ports can extend more than just radially from inner to outer regions. The ports can extend tangentially as vacuum port 145 surrounds reactive gas port 125 and reactive gas port 135. In the embodiment shown in FIGS. 4 and 5, the wedge shaped reactive gas ports 125, 135 are surrounded on all edges, including adjacent the inner peripheral region and outer peripheral region, by a vacuum port 145.

Referring to FIG. 4, as a substrate moves along path 127, each portion of the substrate surface is exposed to the various reactive gases. To follow the path 127, the substrate will be exposed to, or “see”, a purge gas port 155, a vacuum port 145, a first reactive gas port 125, a vacuum port 145, a purge gas port 155, a vacuum port 145, a second reactive gas port 135 and a vacuum port 145. Thus, at the end of the path 127 shown in FIG. 4, the substrate has been exposed to gas streams from the first reactive gas port 125 and the second reactive gas port 135 to form a layer. The injector unit 122 shown makes a quarter circle but could be larger or smaller. The gas distribution assembly 120 shown in FIG. Scan be considered a combination of four of the injector units 122 of FIG. 4 connected in series.

The injector unit 122 of FIG. 4 shows a gas curtain 150 that separates the reactive gases. The term “gas curtain” is used to describe any combination of gas flows or vacuum that separate reactive gases from mixing. The gas curtain 150 shown in FIG. 4 comprises the portion of the vacuum port 145 next to the first reactive gas port 125, the purge gas port 155 in the middle and a portion of the vacuum port 145 next to the second reactive gas port 135. This combination of gas flow and vacuum can be used to prevent or minimize gas phase reactions of the first reactive gas and the second reactive gas.

Referring to FIG. 5, the combination of gas flows and vacuum from the gas distribution assembly 120 form a separation into a plurality of processing regions 250. The processing regions are roughly defined around the individual reactive gas ports 125, 135 with the gas curtain 150 between 250. The embodiment shown in FIG. 5 makes up eight separate processing regions 250 with eight separate gas curtains 150 between. A processing chamber can have at least two processing region. In some embodiments, there are at least three, four, five, six, seven, eight, nine, 10, 11 or 12 processing regions.

During processing a substrate may be exposed to more than one processing region 250 at any given time. However, the portions that are exposed to the different processing regions will have a gas curtain separating the two. For example, if the leading edge of a substrate enters a processing region including the second reactive gas port 135, a middle portion of the substrate will be under a gas curtain 150 and the trailing edge of the substrate will be in a processing region including the first reactive gas port 125.

A factory interface 280, which can be, for example, a load lock chamber, is shown connected to the processing chamber 100. A substrate 60 is shown superimposed over the gas distribution assembly 120 to provide a frame of reference. The substrate 60 may often sit on a susceptor assembly to be held near the front surface 121 of the gas distribution assembly 120 (also referred to as a gas distribution plate). The substrate 60 is loaded via the factory interface 280 into the processing chamber 100 onto a substrate support or susceptor assembly (see FIG. 3). The substrate 60 can be shown positioned within a processing region because the substrate is located adjacent the first reactive gas port 125 and between two gas curtains 150a, 150b. Rotating the substrate 60 along path 127 will move the substrate counter-clockwise around the processing chamber 100. Thus, the substrate 60 will be exposed to the first processing region 250a through the eighth processing region 250h, including all processing regions between. For each cycle around the processing chamber, using the gas distribution assembly shown, the substrate 60 will be exposed to four ALD cycles of first reactive gas and second reactive gas.

The conventional ALD sequence in a batch processor, like that of FIG. 5, maintains chemical A and B flow respectively from spatially separated injectors with pump/purge section between. The conventional ALD sequence has a starting and ending pattern which might result in non-uniformity of the deposited film. The inventors have surprisingly discovered that a time based ALD process performed in a spatial ALD batch processing chamber provides a film with higher uniformity. The basic process of exposure to gas A, no reactive gas, gas B, no reactive gas would be to sweep the substrate under the injectors to saturate the surface with chemical A and B respectively to avoid having a starting and ending pattern form in the film. The inventors have surprisingly found that the time based approach is especially beneficial when the target film thickness is thin (e.g., less than 20 ALD cycles), where starting and ending pattern have a significant impact on the within wafer uniformity performance. The inventors have also discovered that the reaction process to create SiCN, SiCO and SiCON films, as described herein, could not be accomplished with a time-domain process. The amount of time used to purge the processing chamber results in the stripping of material from the substrate surface. The stripping does not happen with the spatial ALD process described because the time under the gas curtain is short.

Accordingly, embodiments of the disclosure are directed to processing methods comprising a processing chamber 100 with a plurality of processing regions 250a-250h with each processing region separated from an adjacent region by a gas curtain 150. For example, the processing chamber shown in FIG. 5. The number of gas curtains and processing regions within the processing chamber can be any suitable number depending on the arrangement of gas flows. The embodiment shown in FIG. 5 has eight gas curtains 150 and eight processing regions 250a-250h. The number of gas curtains is generally equal to or greater than the number of processing regions. For example, if region 250a had no reactive gas flow, but merely served as a loading area, the processing chamber would have seven processing regions and eight gas curtains.

A plurality of substrates 60 are positioned on a substrate support, for example, the susceptor assembly 140 shown FIGS. 1 and 2. The plurality of substrates 60 are rotated around the processing regions for processing. Generally, the gas curtains 150 are engaged (gas flowing and vacuum on) throughout processing including periods when no reactive gas is flowing into the chamber.

A first reactive gas A is flowed into one or more of the processing regions 250 while an inert gas is flowed into any processing region 250 which does not have a first reactive gas A flowing into it. For example if the first reactive gas is flowing into processing regions 250b through processing region 250h, an inert gas would be flowing into processing region 250a. The inert gas can be flowed through the first reactive gas port 125 or the second reactive gas port 135.

The inert gas flow within the processing regions can be constant or varied. In some embodiments, the reactive gas is co-flowed with an inert gas. The inert gas will act as a carrier and diluent. Since the amount of reactive gas, relative to the carrier gas, is small, co-flowing may make balancing the gas pressures between the processing regions easier by decreasing the differences in pressure between adjacent regions.

Typical heaters 105 may not allow the temperature of the substrate to be high enough for efficient reactions. For example, lamps may use a lot of energy and time to heat the susceptor assembly to heat the supported wafers. One or more embodiments of the disclosure advantageously allow the wafers to be heated to higher temperatures than a conventional heater. Some embodiments advantageously provide a heater that prevents or minimizes particulate contamination. One or more embodiments advantageously provide processing chambers which minimize the oxidation or reaction of the graphite heater.

One or more embodiments of the disclosure use resistive graphite heaters as alternate heating sources to traditional aluminum, stainless steel or materials such as Inconel alloy, heaters or lamps. The resistive graphite heater of some embodiments provides adequate heat for processes with varying temperature requirements which include low temperature (e.g., wafer temperature around 75° C.; resistive heater temp about 100° C.), medium temperature (e.g., wafer temperatures about 450° C.; resistive heater temperatures about 550-600° C.) and high temperature processes (e.g., wafer temperatures about 550° C. to greater than 700° C.; resistive heater temperatures about 720° C. to greater than 900° C.). In some embodiments, the graphite heater has a coating or insulator to prevent particle contamination. The enclosed chamber environment can be filled with an inert gas or barriers to prevent or minimize graphite oxidation or reaction with other gases at any time during processing. Some embodiments include temperature measuring devices, current and/or voltage measuring devices.

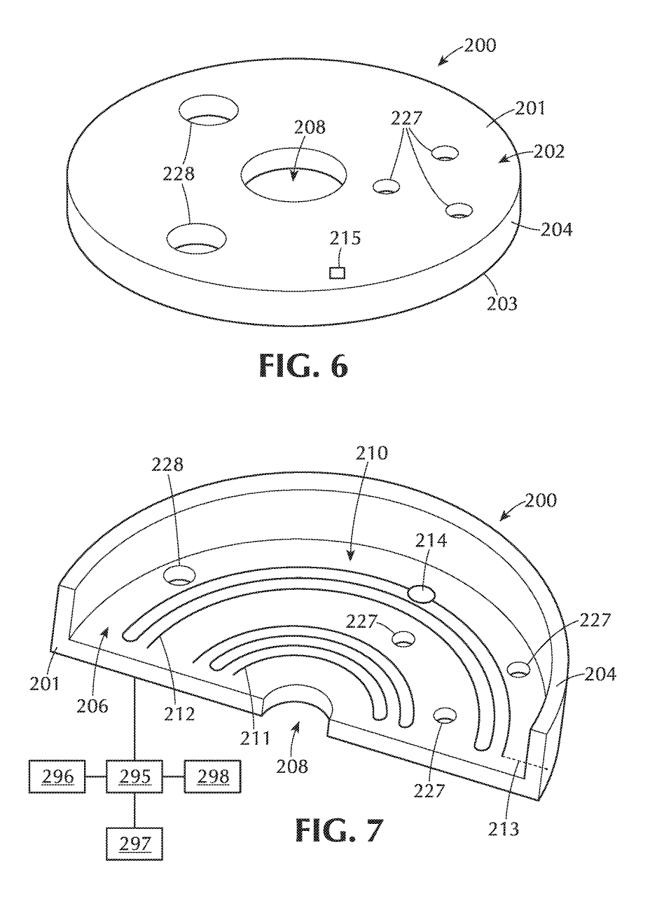

FIG. 6 shows an embodiment of a heating apparatus 200 in accordance with one or more embodiment of the disclosure. FIG. 7 shows a cut-away view of the heating apparatus 200. The heating apparatus 200 can be used for any heating purposes and, in some embodiments, is sized for use with a batch processing chamber. The heating apparatus 200 includes a body 201 with a top surface 202, a bottom surface 203 and an outer edge 204. In use with a batch processing chamber, the top surface 202 of the heating apparatus 200 is positioned adjacent to and a distance D away from a susceptor assembly 140, as shown in FIG. 1. The heating apparatus 200 can also act as a substrate support or susceptor assembly. For example, the susceptor assembly 140 shown in FIG. 1 can be the heating apparatus 200.

The distance D that the heating apparatus 200 is positioned from the susceptor assembly 140 can be varied during processing or fixed. In some embodiments, during use, the heating apparatus 200 is positioned a distance D in the range of about 30 mm to about 140 mm, or in the range of about 50 mm to about 120 mm.

Referring again to FIGS. 6 and 7, the body 201 of the heating apparatus 200 shown has an opening 208 which extends from the top surface 202 to the bottom surface 203 of the body 201. The opening 208 may allow the heating apparatus to be positioned around a component without contacting the component. For example, FIG. 1 shows a heating apparatus around support shaft 160 of the susceptor assembly 140. There may be a space between the heating apparatus and the shaft to prevent contact that may cause damage to either the heating apparatus or the shaft. In some embodiments, the heating apparatus 200 is connected to the support shaft 160 and rotates with the support shaft 160.

Graphite, as a heating apparatus, presented challenges for use in batch processing chambers due to the difficulty of forming electrical connections, particle formation during processing and oxygen reactivity. One or more embodiments of the disclosure advantageously incorporate a graphite heating apparatus into a batch processing chamber. According to some embodiments, the body 201 of the heating apparatus 200 is made of graphite. In some embodiments, the body 201 comprises substantially only graphite, meaning that the composition of the body 201 is greater than about 95% carbon on an atomic basis. In some embodiments, the composition of the body is greater than about 96%, 97%, 98%, 99%, 99.5% or 99.9% carbon on an atomic basis.

Referring to FIG. 7, disposed under the top surface 202 of heating apparatus 200 is a heating element 210. In the embodiment shown, the heating element includes a first resistive heating element 211 that heats a central region or zone and a second resistive heating element 212 that heats an outer region or zone. As used in this regard, “central”, and the like, refers to a region near the center of mass of the heating apparatus so that the central region of the embodiment shown in FIG. 7 is around the opening 208. As used in this regard, the term “outer,” and the like, refers to an area near the outer edge of the component.

The resistive heater of some embodiments is a continuous section of material—which can be planar, round, or other shape—disposed within a recess 206 of body 201. In some embodiments, the resistive heater comprises wound bodies of metal wire. While the embodiment shown has two resistive heaters forming two zones, those skilled in the art will understand that there can be any number of zones or individual heating elements. In some embodiments, there are three resistive heaters forming three zones. In some embodiments, there are four resistive heaters forming four zones. FIG. 7 shows one half of a heating apparatus of one or more embodiments. Those skilled in the art will see that if the heating apparatus was formed of matching halves, there would be four resistive heaters forming four zones with two inner zones and two outer zones, the inner zones spaced at different radii from the center of the heating apparatus than the outer zones. In various embodiments there is 1, 2, 3, 4, 5, 6, 7, 8, 9 or more radial zones. In various embodiments there is 1, 2, 3, 4, 5, 6, 7, 8, 9 or more rotational zones, meaning that the zones are about the same distance from the center of mass and located at different angles of a circle.

In some embodiments, there is more than one layer of resistive heaters. For example, there can be two, three or four resistive heaters stacked, with or without space between each.

All or any of the resistive heating elements may be made from any suitable material known in the art. In some embodiments, the resistive heating element(s) has a coefficient of thermal expansion similar to those of the body 201. An example of a suitable material for the resistive heating elements includes pyrolytic graphite. The resistive heating elements can be disposed within recesses of the body by, e.g., CVD or ALD deposition.

The body 201 of the heating apparatus 200 may be able to withstand temperatures greater than or equal to about 1050° C., 1100° C., 1150° C. or 1200° C. The heating apparatus of some embodiments is sufficient to heat the susceptor assembly 140 and a substrate 60 positioned on the top surface 141 of the susceptor assembly 140 to a temperature greater than or equal to about 650° C., 675° C., 700° C., 720° C., 725° C., 750° C., 775° C. or 800° C.

The body 201 may be coated with a pyrolytic coating; a material that can withstand the high temperatures and corrosive materials associated with CVD and ALD processes. Suitable examples include, but are not limited to, pyrolytic graphite, pyrolytic boron nitride, graphite powder, graphite powder with a silicate glass binder. In some embodiments, the resistive heater is coated with graphite powder with a water based silicate glass binder and then cured in an oven at elevated temperature. In one or more embodiments, a pyrolytic material, for example, pyrolytic boron nitride, is disposed across the top surface 202 of the body. In some embodiments, the pyrolytic material is disposed across the outer surface of the heating apparatus including the top surface, bottom surface and outer edge.

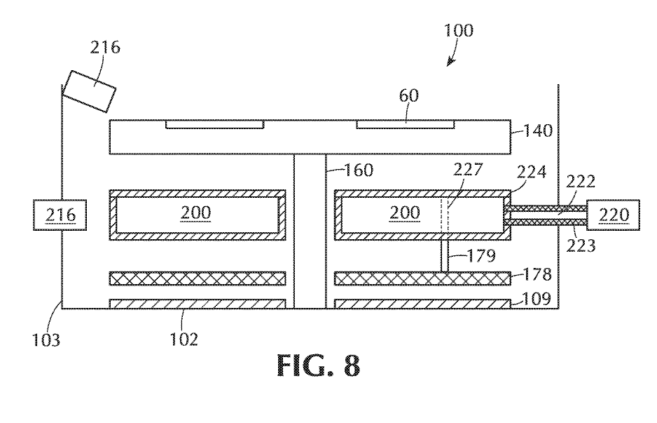

Referring to FIG. 8, the heating apparatus 200 is connected to a suitable power source 220. In some embodiments, the heating apparatus 200 is connected to a 480V power source 220 through power line 222. In some embodiments, the power source has a power in the range of about 100 V to about 500 V. To prevent arcing, some embodiments may include insulation 223 around the power line 222 and/or other components, including but not limited to, the body 201 of the heating apparatus 200. FIG. 8 shows insulation 223 around power line 222 and insulation 224 around heating apparatus 200. In some embodiments, the power line 222 is maintained a distance from other connections to prevent arcing.

Insulation may be used to prevent the heating apparatus 200 from substantially heating other chamber components (e.g., the support post 160). As used in this regard, “substantially heating” means that the lifetime of the component is not shortened by more than 20%. Suitable insulation includes, but is not limited to, quartz, ceramic, aluminum oxide fibers, alumina silica fiber, ceramic fiber and sapphire. In some embodiments, the insulation has a coefficient of thermal expansion within 20% (relative) of the coefficient of thermal expansion of the body 201 of the heating apparatus 200.

Each resistive heating element 211, 212 has a corresponding power line running 213 (see FIG. 7) extending through the body 201 to provide respective electrical power to the resistive heating element. Each of the individual power lines can be independently controlled. Of course, one or more ground lines (not shown) may be provided, also running through the body 201, to complete the circuit of each resistive heating element.

With reference to FIG. 6, the heating apparatus 200 of some embodiments includes one or more openings 227, 228. The openings 227 shown on the right side of FIG. 6 may be used to allow a plurality (in this case three) of lift pins to pass through the heating apparatus 200. Referring to FIG. 8, a lift pin assembly 178 is positioned below the heating apparatus 200 so that the pins 179 (only one is shown) may extend through opening 227 in the heating apparatus 200 in order to reach the susceptor assembly 140. The lift pin assembly may be positioned below the heating apparatus 200 so as not to interfere with heating of the susceptor assembly 140.

In FIG. 6, openings 228 are larger than openings 227 to allow larger components to pass through. For example openings 228 may be provided to allow power connections (not shown) to pass through the heating apparatus 200. The openings 227, 228 are sized to allow the component (e.g., lift pin or power connection) to pass through without contacting the body 201.

Some embodiments include at least one temperature measurement device. The temperature measurement device can be connected to the heating apparatus 200, the heating elements 211, 212 or remote from the heating apparatus. Referring to FIG. 7, a temperature measurement device 214 is connected to heating element 212 and those skilled in the art will understand that there can be additional temperature measurement devices 214 connected to any or all of the heating elements. In some embodiments, the temperature measurement device comprises one or more of a voltmeter or ammeter to measure the voltage or amperage, respectively, of the individual heating elements 211, 212.

In some embodiments, the temperature measurement device 215 (see FIG. 6) is in contact with the body 201 of the heating apparatus 200 to measure the temperature of the heating apparatus 200 body 201 directly. Suitable examples of temperature measurement devices include, but are not limited to, thermistors and thermocouples.

In some embodiments, the temperature measurement device 216 (see FIG. 8) is located remotely from the heating apparatus 200. For example, an optical pyrometer may be positioned to measure the temperature of the heating apparatus 200 body 201 or the susceptor assembly 140 or of the substrate 60.

To prevent or minimize the formation of unwanted particulates, some embodiments include an inert gas to shroud around the heating apparatus 200. Referring to FIG. 1, purge gas injector 106 is positioned to direct a flow of inert gas toward the heating apparatus 200. Without being bound by theory, it is believed that a shroud of inert gas may prevent reaction of the graphite body which may form particulates. The use of the inert gas shroud may also help prevent oxygen, if present, from reactive with the graphite body 201.

In some embodiments, the insulator 224 (see FIG. 8) around the heating apparatus 200 minimizes the potential for reactions with the graphite body 201. The insulator 224 of some embodiments is quartz and forms an enclosure around the body 201 allowing electrical connections. The presence of the quartz insulator has a minimal or negligible effect on heating efficiency because the quartz is transparent to radiant heat from the heating apparatus 200. The effect of conductive heating may be noticeable if the heating apparatus 200 is too close to the susceptor assembly. As will be readily understood by the skilled artisan, if lift pins 179 or other components need to pass through openings 227, 228 in the body 201, there will be suitably sized and positioned openings in the enclosure. In some embodiments, the opening 227 in body 201 are sized and positioned so that the lift pins 179 have a clearance in the range of about 5 mm to about 15 mm from the heater apparatus body 201.

In some embodiments, a reflector 109 (see FIG. 8) is positioned between the bottom surface 203 of the heating apparatus 200 and the bottom 102 of the processing chamber 100. The reflector 109 may be useful in preventing radiant heat from the heating apparatus 200 from affecting the processing chamber. The reflector 109 may also help redirect radiant energy toward the susceptor assembly to increase efficiency. Suitable reflectors include, but are not limited to, aluminum, silver, stainless steel, nickel plated stainless steel, silicon oxide coated stainless steel, silver or gold plated aluminum, silver or gold plated stainless steel, materials with high reflectivity or high emissivity, and high reflectivity or emissivity material painted on stainless steel. The reflector 109 can be positioned any suitable distance from the heating apparatus 200 and the bottom 102 of the chamber 100. In some embodiments, the reflector 109 is positioned a distance in the range of about 10 mm to about 40 mm from the heating apparatus 200.

A control system 295, depicted in FIG. 7, may be used to control the heating apparatus 200. The control system 295 may be part of the control system for a CVD system or ALD system and is electrically connected to the heating apparatus 200. Together, the heating apparatus 200 and the control system 295 form the heating system. Numerous possibilities are available for the physical implementation of the control system 295 and are known to those skilled in the art. Any suitable implementation of the control system 295 may be used, and providing a detailed control system 295 should be a routine task for one of ordinary skill in the art, after reading the disclosure.

According to one embodiment, the control system 295 includes a user input/output (I/O) system 296, a temperature input 297 and a feedback control circuit 298. The user I/O system 296 provides a user interface that allows a user to select a target temperature of the susceptor or substrate or target voltage or amperage of the resistive heaters.

The temperature input 297 may be electrically connected to temperature measurement device to obtain, in real-time, the current temperature. The temperature input 297 then passes this current temperature to the feedback control circuit 298. In a manner familiar to those in the art, the feedback control circuit 298 accepts as input the current temperature and the target temperature and generates a heating power control output. The purpose of the heating power control output is to control the power delivered to the resistive heater so that the temperature as measured by the temperature measurement device tracks as closely as possible the target temperature. The feedback control circuit 298 may be designed to employ any suitable feedback control method known in the art.

Those skilled in the art will appreciate that the control system for controlling the heating apparatus may comprise a plurality a temperature measurement devices or sensors. Each temperature sensor may measure the temperature of a single region or zone. The temperature sensors may include thermocouples, pyrometers or other suitable temperature sensing devices. Combinations of different types of temperature sensors may be used as well.

Although the disclosure herein has been described with reference to particular embodiments, it is to be understood that these embodiments are merely illustrative of the principles and applications of the present disclosure. It will be apparent to those skilled in the art that various modifications and variations can be made to the method, apparatus and system of the present disclosure without departing from the spirit and scope of the disclosure. For example, the outer region of the body of the stage may be divided not into only four zones, but into any number of zones greater than one. In certain embodiments, each of these zones would be provided its respective heating power ratio. Also, the resistive heater zones may overlap with each other. The various heating elements may be on the top surface, bottom surface or embedded in the body of the stage. Zonal temperature measurement may be provided by utilizing multiple temperature measurement devices (thermocouple, pyrometer, etc). Thus, it is intended that the present disclosure include modifications and variations that are within the scope of the appended claims and their equivalents.

What is claimed is:

1. An apparatus comprising:
a body having a top surface, bottom surface and outer edge, the body comprising graphite; and
at least one heating element comprising a continuous section of material disposed within the body.

2. The apparatus of claim 1, wherein the body can withstand temperatures in excess of at least about 1150° C.

3. The apparatus of claim 1, further comprising a pyrolytic coating on the body.

4. The apparatus of claim 1, wherein the heating element comprises pyrolytic graphite.

5. The apparatus of claim 1, wherein the body further comprises an opening passing through the body from the top surface to the bottom surface.

6. The apparatus of claim 1, further comprising a temperature measurement device.

7. The apparatus of claim 6, wherein the temperature measurement device is connected to the at least one heating element and comprises one or more of a voltmeter or an ammeter.

8. The apparatus of claim 6, wherein the temperature measurement device is in contact with body and comprises one or more of a thermistor and a thermocouple.

9. The apparatus of claim 1, wherein there are two or more heating elements arranged in zones radially outwardly from a center of the body.

10. The apparatus of claim 1, wherein the body comprises substantially only graphite.

11. A processing chamber comprising:
a gas distribution assembly having a front surface;
a susceptor assembly having a top surface facing the front surface of the gas distribution assembly and a bottom surface, the top surface having a plurality of recesses therein, each recess sized to support a substrate during processing; and
a heating apparatus having a body comprising graphite with a top surface facing the bottom surface of the susceptor assembly, the heating apparatus including at least one heating element within the body.

12. The processing chamber of claim 11, wherein the heating apparatus is effective to heat the susceptor assembly to a temperature sufficient to heat a substrate positioned on the susceptor assembly to a temperature greater than about 700° C.

13. The processing chamber of claim 11, wherein the heating apparatus is connected to a power source in the range of about 100V to about 500V.

14. The processing chamber of claim 13, further comprising insulation between the power source and adjacent components.

15. The processing chamber of claim 11, wherein the susceptor assembly is supported by a support post and the body of the heating apparatus further comprises an opening passing through the body from the top surface to the bottom surface and the support post passes through the opening in the body without contacting the body.

16. The processing chamber of claim 11, further comprising a temperature measurement device connected to the at least one heating element, the temperature measurement device comprising one or more of a voltmeter or an ammeter.

17. The processing chamber of claim 11, further comprising a temperature measurement device comprising a pyrometer positioned to determine a temperature of substrate on the top surface of the susceptor assembly.

18. The processing chamber of claim 11, further comprising a purge gas injector positioned to direct a flow of inert gas toward the heating apparatus.

19. The processing chamber of claim 11, further comprising a reflector positioned the bottom surface of the heating apparatus and a wall of the processing chamber.

20. A processing chamber comprising:
a gas distribution assembly having a front surface;
a susceptor assembly having a top surface facing the front surface of the gas distribution assembly and a bottom surface, the top surface having a plurality of recesses therein, each recess sized to support a substrate during processing, the susceptor assembly connected to a support post; and
a heating apparatus having a body comprising substantially only graphite with a top surface facing the bottom surface of the susceptor assembly, the heating apparatus including at least one heating element within the body connected to a 100V to 500V power source, the heating element effective to heat the susceptor assembly to a temperature sufficient to heat a substrate positioned on the susceptor assembly to a temperature greater than about 1100° C., the heating apparatus including an opening passing through the body from the top surface to the bottom surface and the support post passes through the opening in the body without contacting the body.
